(19) United States
(12) Patent Application Publication
(10) Pub. No.: US 2007/0063299 A1
(43) Pub. Date: Mar. 22, 2007

(54) CMOS image sensor and method of manufacturing the same

(75) Inventor: Joon Hwang, Cheongjoo-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/525,653

(22) Filed: Sep. 21, 2006

(30) Foreign Application Priority Data
Sep. 22, 2005 (KR) 10-2005-0088087

(51) Int. Cl. H01L 31/0232

(52) U.S. Cl. 257/432; 257/E31.127

(57) ABSTRACT

A CMOS image sensor and a method of manufacturing the same, in which photodiodes of different colors have different depths considering the penetration depth of light into a silicon lattice structure, may also improve characteristics of the image sensor. The CMOS image sensor includes a second conductivity type blue photodiode region, a second conductivity type green photodiode region, a third conductivity type red photodiode region, an insulating layer, a planarization layer, and microlenses. The blue photodiode region is formed to a first depth. The green photodiode region has a second depth greater than the first depth, and is spaced apart from the blue photodiode region at a predetermined distance. The red photodiode region has a third depth greater than the second depth, and is spaced apart from the green photodiode region at a predetermined distance. The insulating layer and the planarization layer are sequentially formed on the semiconductor substrate. The microlenses are formed on the planarization layer, corresponding to the blue, green and red photodiode regions.

### BACKGROUND OF THE INVENTION

This application claims the benefit of Korean Application No. 10-2005-0088087, filed on Sep. 22, 2005, which is incorporated by reference herein in its entirety.

### FIELD OF THE INVENTION

The present invention relates to a CMOS image sensor, and more particularly, to a CMOS image sensor having an improved characteristic and a method of manufacturing the same.

### BACKGROUND OF THE RELATED ART

In general, an image sensor is a semiconductor device that converts an optical image into an electrical signal. The image sensor is largely classified into charge-coupled devices (CCDs) and CMOS image sensors.

The CCD includes a plurality of vertical charge-coupled devices (VCCDs) in which a plurality of photodiodes (PDs) for converting a photo-signal into an electrical signal are arranged in matrix form, a horizontal charge-coupled device (HCCD), and a sense amplifier. The VCCD is formed between the photodiodes, which are vertically arranged in matrix form, and transmits electrical charges generated from each photodiode in the vertical direction. The HCCD transmits the charges, which are transmitted by the VCCD, in a horizontal direction. The sense amplifier senses the charges transmitted in the horizontal direction and outputs an electrical signal.

However, such a CCD has a complicated driving mode, consumes a large amount of power, and needs multi-step photolithography, leading to a relatively complicated manufacturing process. Furthermore, in the conventional CCD, it is difficult to integrate a control circuit, a signal processor, an A/D converter, etc. on a CCD chip, which can make it difficult to miniaturize the CCD.

Recently, in order to overcome the above drawbacks to the charge-coupled device, a CMOS image sensor is drawing wide attraction as a next generation image sensor. In the CMOS image sensor, which uses control and signal processing circuits as peripheral circuits, CMOS technology is employed to form MOS transistors. The number of transistors generally corresponds to the number of unit pixels in a semiconductor substrate. Thus, an output from each unit pixel is sequentially sensed by means of the MOS transistors (e.g., a switching mode may be adopted). That is, in the CMOS image sensor, a photodiode and a MOS transistor are formed in the unit pixel. The CMOS image sensor is adapted to implement an image by sequentially detecting electrical signals of the respective unit pixels according to the switching method.

Since the CMOS image sensor is manufactured through a CMOS manufacturing technology, it has advantages such as relatively low power consumption and a relatively simplified manufacturing process using relatively fewer photolithographic steps. Furthermore, the CMOS image sensor is advantageous in that it facilitates the miniaturization of a product because the control circuit(s), the signal processor(s), an A/D converter, etc., can be integrated on the CMOS image sensor chip. Accordingly, the CMOS image sensor has been widely used in a variety of fields, such as a digital still camera and a digital video camera.

Meanwhile, CMOS image sensors may be classified into a 3T type, a 4T type, a 5T type, and the like according to the number of transistors per unit pixel. The 3T type CMOS image sensor includes one photodiode and three transistors per unit pixel. The 4T type CMOS image sensor includes one photodiode and four transistors per unit pixel.

An equivalent circuit and a layout diagram of the unit pixel of the 4T type CMOS image sensor will now be described below.

FIG. 1 is an equivalent circuit diagram of a general 4T type CMOS image sensor. FIG. 2 is a layout diagram showing a unit pixel of the general 4T type CMOS image sensor.

As shown in FIG. 1, a unit pixel 100 of a CMOS image sensor includes a photodiode (PD) 10 as a photoelectric transformation unit, four transistors, and so on. The four transistors include a transfer transistor 20, a reset transistor 30, a drive transistor 40 and a select transistor 50. To an output terminal OUT of each unit pixel 100 is electrically connected a load transistor 60. In FIG. 1, reference numeral FD denotes a floating diffusion region, Tx denotes a gate voltage of the transfer transistor 20, Rx denotes a gate voltage of the reset transistor 30, Dx denotes a gate voltage of the drive transistor 40, and Sx denotes a gate voltage of the select transistor 50.

In the unit pixel of the general 4T type CMOS image sensor, an active region is defined and isolation layers are formed in portions other than the active region, as shown in FIG. 2. One PD is formed in a relatively wide portion of the active region, and gate electrodes 23, 33, 43 and 53 of the four transistors 20, 30, 40 and 50 are formed in the remaining portions. That is, the transfer transistor 20 is formed by the gate electrode 23, the reset transistor 30 is formed by the gate electrode 33, the drive transistor 40 is formed by the gate electrode 43, and the select transistor 50 is formed by the gate electrode 53. An impurity ion is implanted into the portions of the active regions of the respective transistors except for the bottoms of the gate electrodes 23, 33, 43 and 53, thus forming source/drain regions S/D of the respective transistors.

FIGS. 3a to 3h are cross-sectional views illustrating a conventional method of manufacturing a CMOS image sensor taken along line I-I′ in FIG. 2.

Referring to FIG. 3a, an epitaxial process is performed to form a high-concentration p++ type semiconductor substrate 61 on a low-concentration p− type epitaxial layer 62. An active region and isolation regions are defined in the semiconductor substrate 61. Isolation layers 63 are formed in the isolation regions by a STI process or a LOCOS process.

Thereafter, a gate insulating layer 64 and a conductive layer (for example, a high-concentration doped polycrystalline silicon layer) are sequentially deposited on the epitaxial layer 62 in which the isolation layers 63 are formed. The conductive layer and the gate insulating layer are selectively stripped to form a gate electrode 65.

Referring to FIG. 3b, a first photoresist layer 66 is coated on the entire surface including the gate electrode 65. The first photoresist layer 66 is patterned by exposure and development processes so that the photodiode region is covered and the source/drain region of each transistor is exposed. A low-concentration n− type impurity ion is implanted into the exposed source/drain region using the patterned first photoresist layer 66 as a mask, forming an n− type diffusion region 67.

Referring to FIG. 3c, after the first photoresist layer 66 is stripped, a second photoresist layer 68 is coated on the entire surface. The second photoresist layer 68 is patterned by exposure and development processes so that the respective photodiode regions of the blue, green and red are exposed. A low-concentration n− type impurity ion is then implanted into the epitaxial layer 62 using the patterned second photoresist layer 68, thereby forming blue, green and red photodiode regions 69.

The implementation of the impurity ion for forming the respective photodiode regions 69 is performed using an energy higher than that of the low-concentration n− type diffusion region 67 of the source/drain region. The respective photodiode regions 69 have a depth greater than that of the low-concentration n− type diffusion region 67. Furthermore, each of the photodiode regions 69 corresponds to the source region of the reset transistor (Rx in FIGS. 1 and 2).

Meanwhile, if a reverse bias is applied between each of the photodiode regions 69 and the low-concentration p− type epitaxial layer 62, a depletion layer is generated. Electrons generated by the depletion layer to which light is applied lower a drive transistor potential when the reset transistor is turned off. The electrons continue to lower the potential until the reset transistor is turned on and is then turned off, thereby generating a voltage difference. Accordingly, the operation of the image sensor can be obtained using the voltage difference as a signal process.

The respective photodiode regions 69 have the same depth A of 2 to 4 μm. That is, an impurity ion having the same ion implantation energy is implanted into the respective photodiode regions 69 so that they have the same depth.

Referring to FIG. 3d, the second photoresist layer 68 is completely stripped and an insulating layer is then deposited on the entire surface. Thereafter, an etch-back process is performed to form sidewall insulating layers 70 at sides of the gate electrode 65.

Thereafter, a third photoresist layer 71 is coated on the semiconductor substrate 61. The third photoresist layer 71 is patterned by exposure and development processes so that the photodiode region is coated and the source/drain region of each transistor is exposed. A high-concentration n+ type impurity ion is implanted into the exposed source/drain region using the patterned third photoresist layer 71 as a mask, forming an n+ type diffusion region 72.

Referring to FIG. 3e, the third photoresist layer 71 is stripped. A fourth photoresist layer 73 is coated on the entire surface. The fourth photoresist layer 73 is patterned by exposure and development processes so that the respective photodiode regions are exposed. Thereafter, a p⁰ type impurity ion is implanted into the photodiode region in which the n-type diffusion region 69 is formed using the patterned fourth photoresist layer 73 as a mask, thereby forming a p⁰type diffusion region 74 within the surface of the semiconductor substrate.

Referring to FIG. 3f, the fourth photoresist layer 73 is stripped. A thermal treatment process is performed on the semiconductor substrate 61 in order to diffuse and/or activate each impurity diffusion region.

Thereafter, an interlayer insulating layer 75 is formed on the entire surface. A metal layer is formed on the interlayer insulating layer 75 and is selectively patterned to form a variety of metal lines (not shown). Meanwhile, the interlayer insulating layer 75 and the metal lines may be formed in various layers. A first planarization layer 76 is then formed on the interlayer insulating layer 75.

Referring to FIG. 3g, blue, red and green resist layers are coated on the first planarization layer 76. Exposure and development processes are performed on the blue, red and green resist layers, thus forming color filter layers 77 for filtering light per a wavelength range. The respective color filter layers 77 have different steps since they are formed by different photolithography and etch processes.

Referring to FIG. 3h, a second planarization layer 78 is formed on the entire surface including the polished color filter layers 77. A material layer for forming a microlens is coated on the second planarization layer 78. The material layer is patterned by exposure and development processes, forming a microlens pattern. Thereafter, the microlens pattern is reflowed to form a microlens 79.

However, the conventional manufacturing method of the CMOS image sensor has the following problems.

That is, the photodiodes of the three primary colors (e.g., blue, green and red) have the same depth. The wavelengths of light corresponding to each of the three primary colors have significantly different penetration depths from the silicon surface to the blue (B), green (G) and red (R) photodiodes due to a difference in the wavelength opposite to the silicon lattice structure. In particular, since the photodiodes do not play an optimally effective role in blue and red pixels, characteristics of an image sensor are degraded.

### SUMMARY OF THE INVENTION

Accordingly, the present invention has been made in view of the above problems, and it is an object of the present invention to provide a CMOS image sensor and a method of manufacturing the same, in which blue, green and red photodiodes have different depths considering the penetration depth of light into a silicon lattice structure due to a difference in the wavelengths of the three primary colors, thereby improving characteristics of the image sensor.

To achieve the above object, a CMOS image sensor according to an embodiment of the present invention includes a blue photodiode region, a green photodiode region, and a red photodiode region, each having a second conductivity type; an insulating layer, a planarization layer, and one or more microlenses. The blue photodiode region is formed at a first depth in a first conductivity type semiconductor substrate. The green photodiode region has a second depth greater than the first depth, and is at least a first predetermined distance from the blue photodiode region. The red photodiode region has a third depth greater than the second depth, and is at least a second predetermined distance from the green photodiode region. The insulating layer and the planarization layer are sequentially formed on the semiconductor substrate. The microlenses are formed on the planarization layer, corresponding to the blue, green and red photodiode regions.

A method of manufacturing a CMOS image sensor according to another embodiment of the present invention includes the steps of growing a first conductivity type epitaxial layer on the semiconductor substrate; implanting a second conductivity type impurity ion into a predetermined region of the epitaxial layer, thus forming a blue photodiode region having a first depth; forming a green photodiode region having a second depth greater than the first depth by implanting a second conductivity type impurity ion into a predetermined region of the epitaxial layer, wherein the green photodiode region is at least a first predetermined distance from the blue photodiode region; forming a red photodiode region having a third depth greater than the second depth by implanting a second conductivity type impurity ion into a predetermined region of the epitaxial layer, wherein the red photodiode region is at least a second predetermined distance from the green photodiode region; sequentially forming an insulating layer and a planarization layer on the semiconductor substrate; and forming a micro lens on the planarization layer to correspond to one of the green, blue and red photodiode regions.

### BRIEF DESCRIPTION OF THE DRAWINGS

Further objects and advantages of the invention can be more fully understood from the following detailed description taken in conjunction with the accompanying drawings in which:

FIG. 1 is an equivalent circuit diagram of a general 4T type CMOS image sensor;

FIG. 2 is a layout diagram showing a unit pixel of the general 4T type CMOS image sensor;

FIGS. 3a to 3h are cross-sectional views illustrating a conventional method of manufacturing a CMOS image sensor taken along line I-I′ FIG. 2;

FIG. 4 is a cross-sectional view of a CMOS image sensor according to an embodiment of the present invention; and

FIGS. 5a to FIG. 7b are cross-sectional views illustrating a method of manufacturing the CMOS image sensor taken along line I-I′ FIG. 2 according to an embodiment of the present invention.

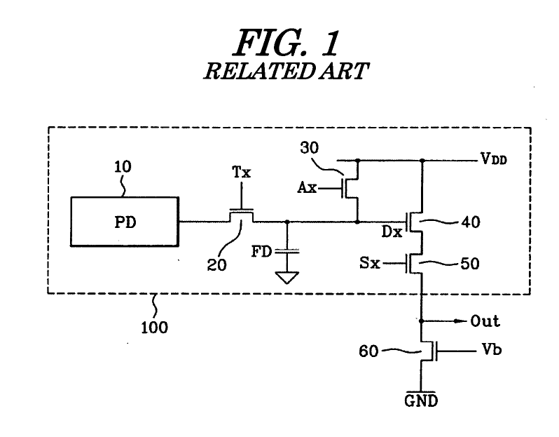

### DETAILED DESCRIPTION OF THE PREFERRED EMBODIMENT

A CMOS image sensor and a method of manufacturing the same according to the present invention will now be described in detail in connection with specific embodiments with reference to the accompanying drawings.

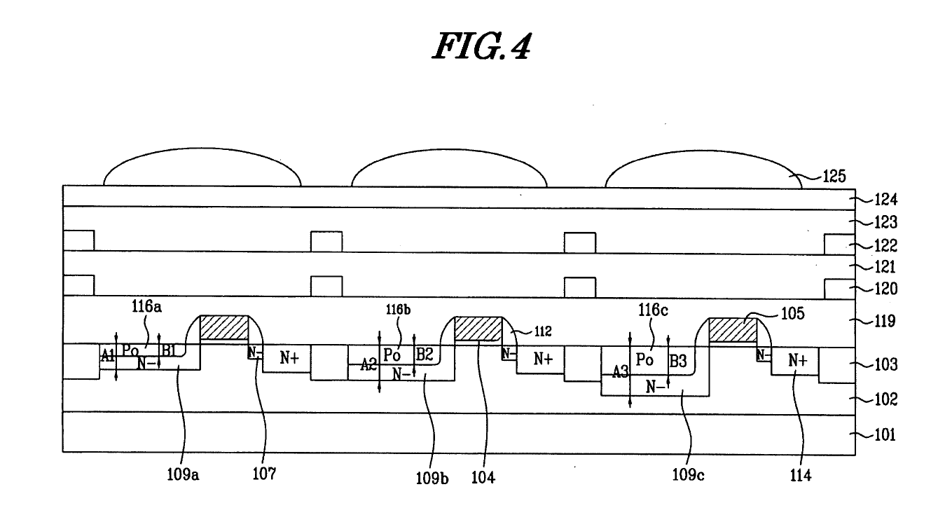

FIG. 4 is a cross-sectional view of a CMOS image sensor according to an embodiment of the present invention.

Referring to FIG. 4, the CMOS image sensor according to an embodiment of the present invention includes a first conductivity type (p-type) epitaxial layer 102 formed on a first conductivity type (p++ type) semiconductor substrate 101. A second conductivity type (n− type) blue photodiode region 109 may have a depth of 0.5 μm or less, a second conductivity type (n− type) green photodiode region 109b, spaced apart from the blue photodiode region 109a at a first predetermined distance, may have a depth of 1.5 to 3.0 μm, and a second conductivity type (n− type) red photodiode region 109c may be spaced apart from the green photodiode region 109b at a second predetermined distance and have a depth of 4.0 to 5.0 μm. Each photodiode region is generally formed in the epitaxial layer 102. The first and second predetermined distances are preferably the same, but may be different (e.g., when the red photodiode is positioned between the blue and green photodiodes). Also, the photodiodes may represent or include other color systems (e.g., the yellow-cyan-magenta, or YCM, system). First to third impurity regions 116a, 116b and 116c of a first conductivity type (p0 type), are generally formed within the blue, green and red photodiode regions 109a, 109b and 109c, respectively, at different depths. First, second and third (interlayer) insulating layers 119, 121 and 123 and a planarization layer 124 are formed on the semiconductor substrate 101, and microlenses 125 are formed on the planarization layer 124. Generally, each microlens 125 corresponds to and/or is positioned over one of the blue, green and red photodiode regions 109a, 109b and 109c, respectively.

Furthermore, the first impurity region 116a of the first conductivity type may have a thickness of 0.1 μm or less. The second impurity region 116b of the first conductivity type may have a thickness of 0.5 to 1.0 μm or less. The third impurity region 116c of the first conductivity type may have a thickness of about 2.0 to 3.0 μm. Also, the epitaxial layer 102 may have a thickness of about 4 to 7 μm.

Furthermore, first and second metal lines 120 and 122 may be formed on the first and second (interlayer) insulating layers 119 and 121, respectively. The third interlayer insulating layer 123 is formed on the entire surface of the underlying insulator layer 121, including the second metal line 122. In this example, the metal lines 120 and 122 comprise conventional aluminum metallization, formed by conventional photolithography, but they could also comprise conventional (dual) damascene copper metallization.

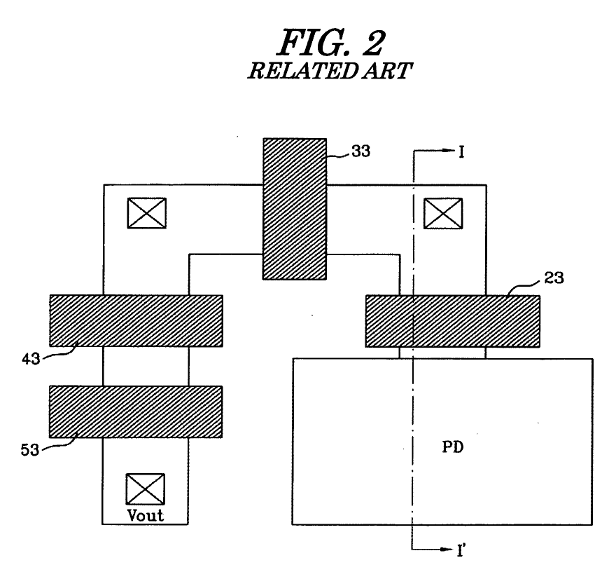

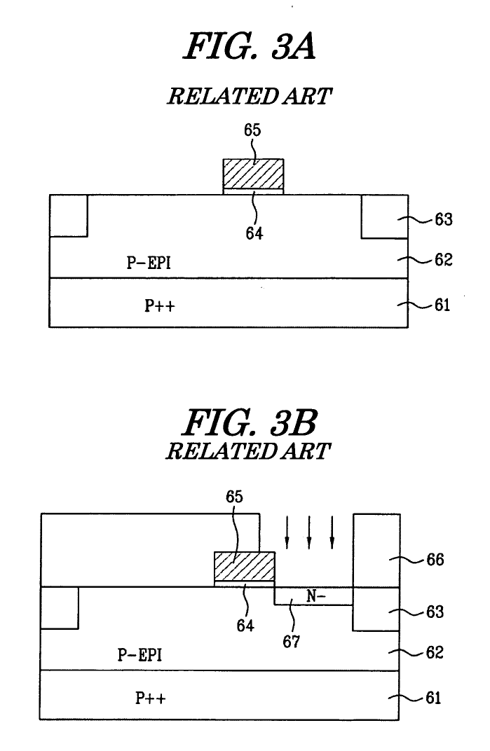

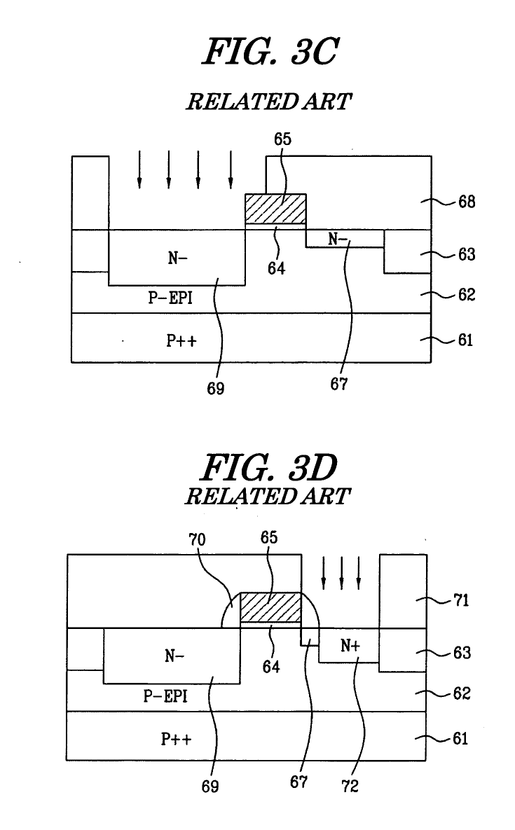

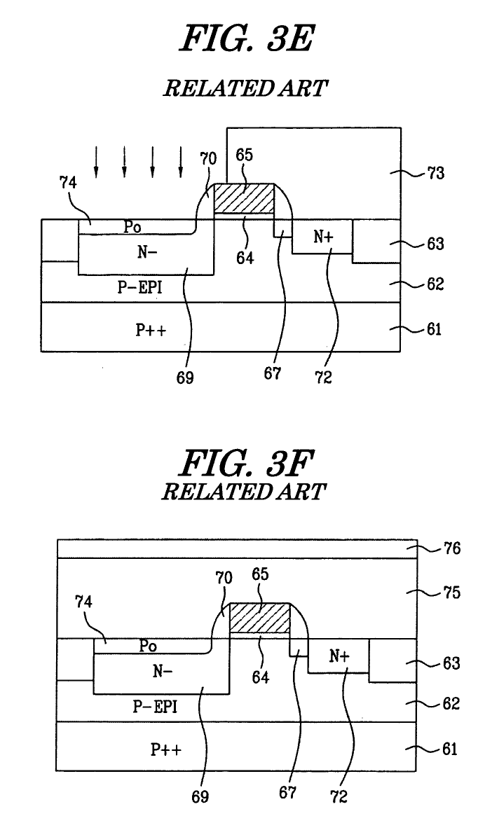

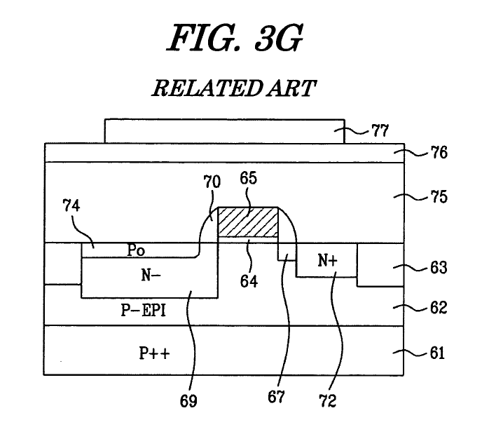

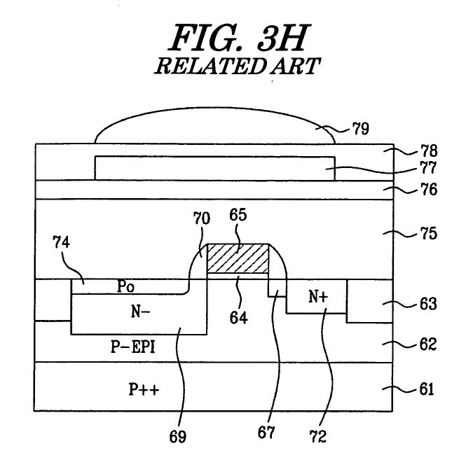

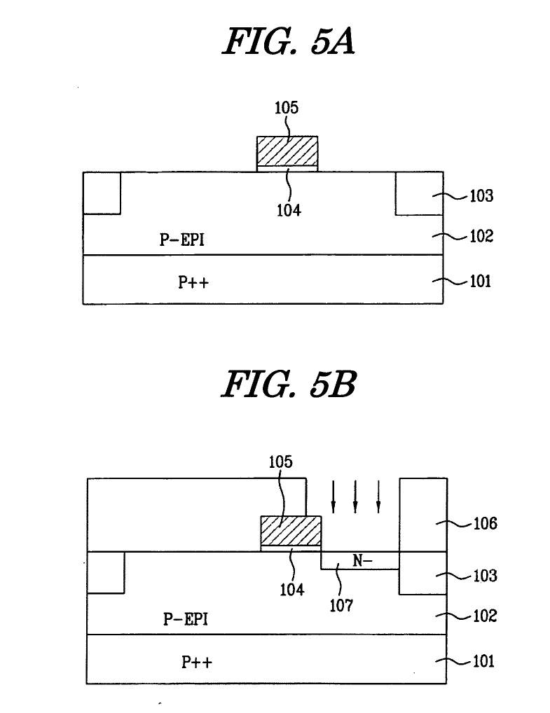

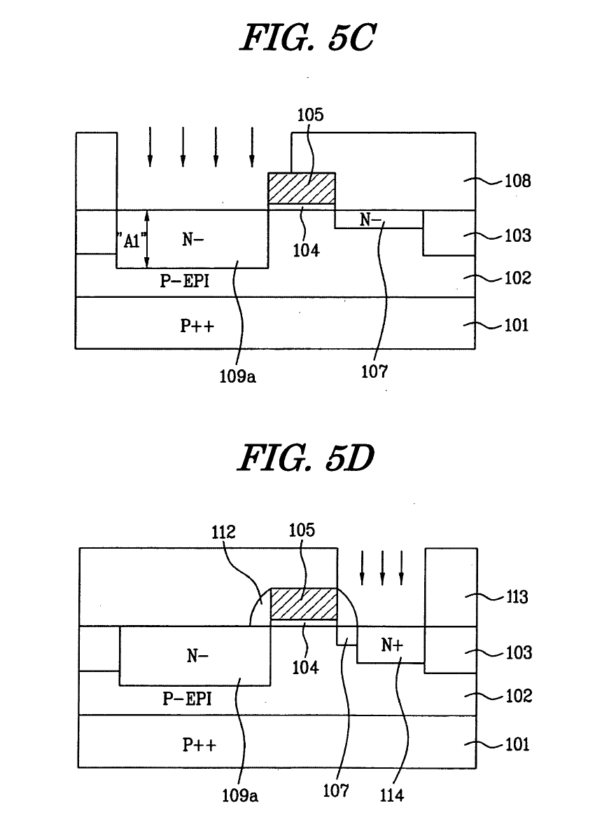

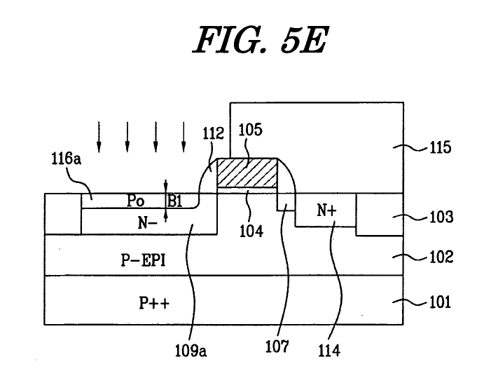

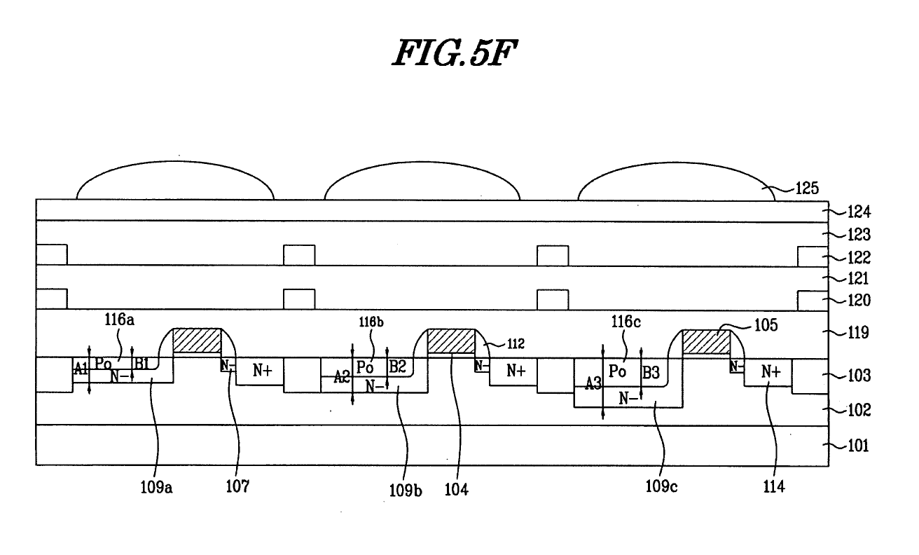

FIGS. 5a to 7b are cross-sectional views illustrating a method of manufacturing the CMOS image sensor taken along line I-I′ in FIG. 2 according to an embodiment of the present invention.

Referring to FIG. 5a, the first conductivity type (p− type) epitaxial layer 102 of a low concentration is formed on the semiconductor substrate 101, such as a first conductivity type (p++ type) single crystal silicon of a high concentration, by an epitaxial process. Thus, the epitaxial layer 102 may comprise silicon and/or germanium (preferably silicon), and be doped conventionally or by mixing a dopant precursor gas (such as a borane or trihaloborane) with the gas mixture used in the epitaxial growth of layer 102. The epitaxial layer 102 has a large and deep depletion region formed in the photodiode. This is for the purpose of increasing the ability of a low voltage photodiode for collecting optical charges and improving the optical sensitivity.

Meanwhile, the semiconductor substrate 101 may be an n type substrate. A p type epitaxial layer (e.g., 102) may be formed on the n type substrate. The p− type epitaxial layer 102 may have a thickness B of 4 to 7 μm. Thereafter, isolation layers 103 are formed in the epitaxial layer 102 by conventional STI and/or LOCOS processes. Though not shown in the drawings, a method of forming the isolation layers 103 will be described below.

First, a pad oxide film, a pad nitride film and a Tetra Ethyl Ortho Silicate (TEOS) oxide layer may be sequentially formed on the semiconductor substrate. A photoresist layer is formed on the TEOS oxide layer. The photoresist layer is exposed and developed using a mask defining the active region and the isolation region, thus patterning the photoresist layer. At this time, the photoresist layer of the isolation region is stripped. Thereafter, the pad oxide film, the pad nitride film and the TEOS oxide layer of the isolation region are selectively etched using the patterned photoresist layer as a mask. The semiconductor substrate of or in the isolation region is etched to a predetermined thickness using the patterned pad oxide film, the pad nitride film and the TEOS oxide layer as a mask, thus forming a trench. The photoresist layer is all stripped.

Thereafter, a sacrificial oxide layer is thinly formed on the entire surface in which the trench is formed. An oxide layer (e.g., an O₃ TEOS layer) is deposited on the substrate so that the trench or gap is filled. The sacrificial oxide layer may also be formed on the inner walls of the trench, and the O₃ TEOS may be formed at a temperature of about 1000° C. or more. Thereafter, the O₃ TEOS layer is planarized by a Chemical Mechanical Polishing (CMP) process so that it remains only within the trench region, thus forming the isolation layer 103 within the trench. The pad oxide film, the pad nitride film and the TEOS oxide layer are then stripped.

Thereafter, a gate insulating layer 104 and a conductive layer (for example, a highly doped polycrystalline silicon layer) are sequentially formed on the entire surface of the epitaxial layer 102 in which the isolation layer 103 is formed. The gate insulating layer 104 may be formed by a thermal oxidization process or CVD. The conductive layer and the gate insulating layer are then patterned by conventional photolithography and etching to form a gate electrode 105.

Referring to FIG. 5b, a first photoresist layer 106 is coated on the entire surface including the gate electrode 105. The first photoresist layer 106 is patterned by exposure and development processes so that it covers each photodiode region and exposes the source/drain region of each transistor. A second conductivity type (n− type) impurity ion of a low concentration is implanted into the exposed source/drain region using the patterned first photoresist layer 106 as a mask, forming a second conductivity type diffusion region 107.

Referring to FIG. 5c, after the first photoresist layer 106 is stripped, a second photoresist layer 108 is coated on the entire surface. The second photoresist layer 108 is patterned by exposure and development processes so that the blue photodiode region is exposed. A second conductivity type (n− type) impurity ion of a low concentration is implanted into the epitaxial layer 102 using the patterned second photoresist layer 108 as a mask, thus forming the blue photodiode region 109a. The blue photodiode region 109a may have a depth A1 of about 0.5 μm from the surface.

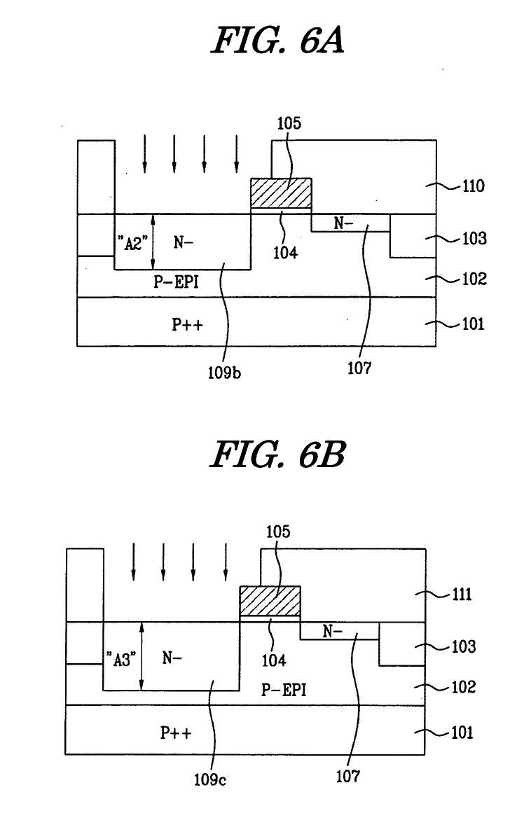

Referring to FIG. 6a, after the second photoresist layer 108 is completely stripped, a third photoresist layer 110 is coated on the entire surface. The third photoresist layer 110 is patterned by exposure and development processes so that the green photodiode region is exposed. A second conductivity type (n− type) impurity ion of a low concentration is implanted into the epitaxial layer 102 using the patterned third photoresist layer 110 as a mask, thereby forming the green photodiode region 109b. The green photodiode region 109b may have a depth A2 of about 1.5 to 3.0 μm from the surface.

Referring to FIG. 6b, after the third photoresist layer 110 is completely stripped, a fourth photoresist layer 111 is coated on the entire surface. The fourth photoresist layer 111 is patterned by exposure and development processes so that the red photodiode region is exposed. A second conductivity type (n− type) impurity ion of a low concentration is then implanted into the epitaxial layer 102 using the patterned fourth photoresist layer 111 as a mask, thereby forming the red photodiode region 109c. The red photodiode region 109c may have a depth A3 of about 4.0 to 5.0 μm from the surface.

The impurity ions for forming the respective blue, green and red photodiode regions 109a, 109b and 109c are implanted with energy higher than that of the low-concentration n-type diffusion region 107 of the source/drain region so that the respective blue, green and red photodiode regions 109a, 109b and 109c are deeper than the low-concentration n-type diffusion region 107.

Referring to FIG. 5d, the fourth photoresist layer 111 is completely stripped, and an insulating layer is deposited on the entire surface. An etch-back process (e.g., anisotropic etching) is performed on the insulating layer to form sidewall insulating layers 112 on lateral surfaces of the gate electrode(s) 105. Thereafter, a fifth photoresist layer 113 is formed on the entire surface in which the sidewall insulating layers 112 are formed. The fifth photoresist layer 113 is patterned by exposure and development processes so that each photodiode region is covered and the source/drain region of each transistor is exposed. Thereafter, a high-concentration n+ type impurity ion is implanted into the exposed source/drain region using the patterned fifth photoresist layer 113 as a mask, thus forming an n+ type diffusion region 114.

Referring to FIG. 5e, after the fifth photoresist layer 113 is stripped, a sixth photoresist layer 115 is coated on the entire surface. The sixth photoresist layer 115 is patterned by exposure and development processes so that the respective photodiode regions are exposed. Thereafter, a first conductivity type (p0 type) impurity ion is implanted into the epitaxial layer 102 in which the blue photodiode region 109a is formed using the patterned sixth photoresist layer 115 as a mask, thereby forming the first p⁰ type diffusion region 116a within the epitaxial layer 102. The first p⁰type diffusion region 116a may have a depth B1 of 0.1 μm or less.

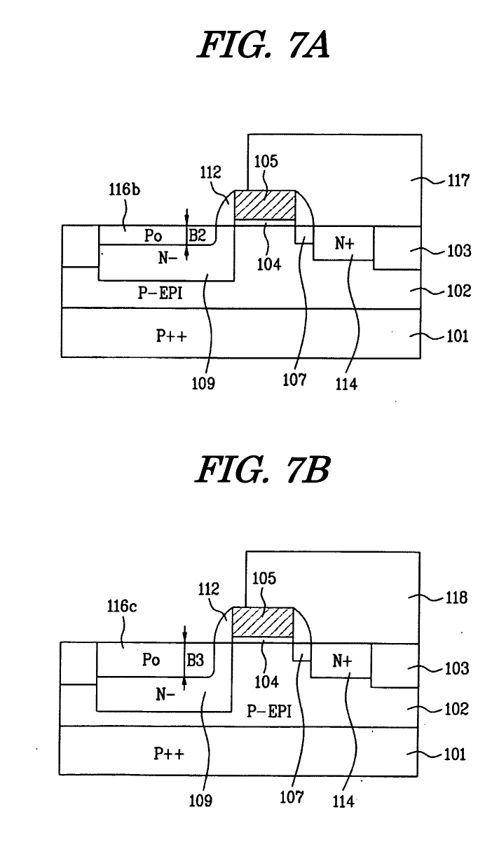

Referring to FIG. 7a, after the sixth photoresist layer 115 is stripped, a seventh photoresist layer 117 is coated on the entire surface. The seventh photoresist layer 117 is patterned by photolithography and development processes so that the respective photodiode regions are exposed. Thereafter, a first conductivity type (p⁰ type) impurity ion is implanted into the epitaxial layer 102 in which the green photodiode region 109b is formed using the patterned seventh photoresist layer 117 as a mask, thereby forming the second p⁰ type diffusion region 116b within the epitaxial layer 102. The second p⁰ type diffusion region 116b may have a depth B2 of about 0.5 to 1.0 μm.

Referring to FIG. 7b, after the seventh photoresist layer 117 is stripped, an eighth photoresist layer 118 is coated on the entire surface. The eighth photoresist layer 118 is patterned by exposure and development processes so that the respective photodiode regions are exposed. Thereafter, a first conductivity type (p⁰ type) impurity ion is implanted into the epitaxial layer 102 in which the red photodiode region 109c is formed using the patterned eighth photoresist layer 118 as a mask, thereby forming the third p⁰ type diffusion region 116c within the epitaxial layer 102. The third p⁰ type diffusion region 116c may have a depth B3 of about 2.0 to 3.0 μm.

Referring to FIG. 5f, after the eighth photoresist layer 118 is stripped, a thermal treatment process is performed on the semiconductor substrate 101 in order to diffuse and/or activate the respective impurity diffusion regions.

Thereafter, a first insulating layer 119 is formed on the entire surface, and optionally planarized (e.g., by CMP), then a metal layer is deposited on the first insulating layer 119. The metal layer is selectively patterned to form first metal lines 120.

A second insulating layer 121 is formed on the entire surface of first insulating layer 119, including the first metal line 120. The second insulating layer 121 is optionally planarized (e.g., by CMP). A metal layer is then deposited on the second insulating layer 121. The metal layer is selectively patterned to form second metal lines 122.

Thereafter, a third insulating layer 123 is formed on the entire surface including the second metal line 122. The third insulating layer 123 is optionally planarized (e.g., by CMP), and a planarization layer 124 is formed on the third insulating layer 123.

Meanwhile, the first, second and third insulating layers 119, 121 and 123, and the first and second metal lines 120 and 122 may be formed in (and/or may comprise) several layers, as is known in the art.

Thereafter, a material layer for a microlens is deposited on the planarization layer 124 and is then selectively patterned to form a microlens pattern. A reflow process is then performed at a temperature of 150 to 200° C., thus forming microlenses 125 corresponding to the blue, green and red photodiode regions 109a, 109b and 109c. That is, after the material layer for the microlens is coated on the planarization layer 124, it is patterned by exposure and development processes to form the microlens pattern. In this case, an oxide layer, such as resist or TEOS, may be used as the material layer for the microlens. The microlens pattern is reflowed to form the microlens 125, but the reflow temperature may be a little higher and/or the length of reflow time may be a little longer when the reflow material case is TEOS, rather than a conventional photoresist material.

The reflow process may be performed using a hot plate or a furnace. At this time, the curvature of the microlens 125 is changed according to a contraction and heating method. Focusing efficiency depends on the curvature.

Thereafter, ultraviolet rays are irradiated to harden the microlens 125. The microlens 125 can maintain an optimal curvature radius because ultraviolet rays are irradiated to harden the microlens 125.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

As described above in detail, the CMOS image sensor and the method of manufacturing the same according to a present invention have the following advantages.

That is, blue (B), green (G) and red (R) wavelengths differ in the penetration depths of the semiconductor substrate. Accordingly, the photodiode regions are formed to be regions with a high potential well so that photoelectrons are generated by corresponding light energy. It is therefore possible to simplify the process and save costs without the need to form color filters (thereby reducing the number of processing steps). Furthermore, light sensitivity can be improved because losses of light energy to be detected in the photodiode due to absorption by a color filter may be avoided.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. A CMOS image sensor, comprising:
a second conductivity type first photodiode region at a first depth in a first conductivity type semiconductor substrate;
a second conductivity type second photodiode region at a second depth in the semiconductor substrate, the second depth being greater than the first depth, the second photodiode region being a first predetermined distance from the first photodiode region at;
a third conductivity type third photodiode region at a third depth in the semiconductor substrate, the third depth being greater than the second depth, the third photodiode region being a second predetermined distance from the second photodiode region;
an insulating layer and a planarization layer on the semiconductor substrate; and
a plurality of micro lenses on the planarization layer, corresponding to the first, second and third photodiode regions.

2. The CMOS image sensor of claim 1, wherein the first depth is 0.5 μm or less.

3. The CMOS image sensor of claim 1, wherein the second depth is in a range of from 1.5 to 3.0 μm, inclusive.

4. The CMOS image sensor of claim 1, wherein the third depth is in a range of from 4 to 5 μm, inclusive.

5. The CMOS image sensor of claim 1, further comprising first conductivity type impurity regions having different depths in the first, second and third photodiode regions of the semiconductor substrate.

6. The CMOS image sensor of claim 5, wherein the first conductivity type impurity region in the first photodiode region has a depth of 0.1 μm or less.

7. The CMOS image sensor of claim 5, wherein the first conductivity type impurity region in the second photodiode region has a depth of from 0.5 to 1.0 μm.

8. The CMOS image sensor of claim 5, wherein the first conductivity type impurity region in the third photodiode region has a depth of from 2.0 to 3.0 μm.

9. The CMOS image sensor of claim 1, wherein the first, second and third photodiode regions comprise blue, green and red photodiode regions, respectively.

10. A method of manufacturing a CMOS image sensor, comprising the steps of:
growing a first conductivity type epitaxial layer on a semiconductor substrate;
implanting second conductivity type impurity ions into a predetermined region of the epitaxial layer, thus forming a first photodiode region having a first depth;
forming a second photodiode region having a second depth greater than the first depth by implanting second conductivity type impurity ions into a predetermined region of the epitaxial layer, wherein the second photodiode region is at least a first predetermined distance from the first photodiode region;
forming a third photodiode region having a third depth greater than the second depth by implanting second conductivity type impurity ions into a predetermined region of the epitaxial layer, wherein the third photodiode region is at least a second predetermined distance from the second photodiode region;
sequentially forming an insulating layer and a planarization layer on the entire surface of the semiconductor substrate; and
forming a microlens on or over the planarization layer to correspond to the green, blue and red photodiode regions.

11. The method of claim 10, wherein the first photodiode region has a depth of 0.5 μm or less.

12. The method of claim 10, wherein the second photodiode region has a depth of 1.5 to 3.0 μm.

13. The method of claim 10, wherein the third photodiode region has a depth of 4 to 5 μm.

14. The method of claim 10, further comprising the step of forming first conductivity type impurity regions having different depths in the first, second and third photodiode regions of the epitaxial layer.

15. The method of claim 14, wherein the first conductivity type impurity region is formed in the first photodiode region to a depth of 0.1 μm or less.

16. The method of claim 14, wherein the first conductivity type impurity region is formed in the second photodiode region to a depth of 0.5 to 1.0 μm.

17. The method of claim 14, wherein the first conductivity type impurity region is formed in the third photodiode region to a depth of 2.0 to 3.0 μm.

18. The method of claim 10, wherein the epitaxial layer has a thickness of 4 to 7 μm.

19. The method of claim 10, wherein the first, second and third photodiode regions comprise blue, green and red photodiode regions, respectively.
